(19) United States
(12) Patent Application Publication
(10) Pub. No.: US 2025/0336440 A1
(43) Pub. Date: Oct. 30, 2025

(54) VARIABLE RESISTANCE NONVOLATILE STORAGE DEVICE AND METHOD FOR DRIVING VARIABLE RESISTANCE NONVOLATILE STORAGE ELEMENT

(71) Applicant: Nuvoton Technology Corporation Japan, Kyoto (JP)

(72) Inventors: Masahiro MORIMOTO, Hyogo (JP); Shunsaku MURAOKA, Osaka (JP); Satoshi AWAMURA, Kyoto (JP); Takeshi OHARA, Kyoto (JP); Satoru FUJII, Osaka (JP)

(21) Appl. No.: 19/261,617

(22) Filed: Jul. 7, 2025

Related U.S. Application Data
(63) Continuation of application No. PCT/JP2024/003582, filed on Feb. 2, 2024.

(30) Foreign Application Priority Data
Feb. 7, 2023 (JP) 2023-017016

(51) Int. Cl. G11C 13/00

(52) U.S. Cl. CPC G11C 13/0033; G11C 13/0069; G11C 2013/008

(57) ABSTRACT

A variable resistance nonvolatile storage device includes a memory cell and a heater thermally coupled to the memory cell, and the memory cell and the heater are independently operable. The memory cell includes a first electrode layer, a second electrode layer, and a variable resistance layer sandwiched between the first electrode layer and the second electrode layer, and the heater includes a heating element, and a third terminal and a fourth terminal each connected to the heating element.

### CROSS REFERENCE TO RELATED APPLICATIONS

This is a continuation application of PCT International Patent Application No. PCT/JP2024/003582 filed on Feb. 2, 2024, designating the United States of America, which is based on and claims priority of Japanese Patent Application No. 2023-017016 filed on Feb. 7, 2023. The entire disclosures of the above-identified applications, including the specifications, drawings and claims are incorporated herein by reference in their entirety.

### FIELD

The present disclosure relates to a variable resistance nonvolatile storage device and a method for driving a variable resistance nonvolatile storage element, particularly relates to a variable resistance nonvolatile storage device that can reduce deterioration of retention, or the like.

### BACKGROUND

In recent years, a technique has been proposed that improves the retention characteristics of a variable resistance nonvolatile storage device (hereinafter, also referred to as a “Resistive Random Access Memory (ReRAM)”) (see PTL 1).

In the technique of PTL 1, in a first write process, a first write pulse is applied to a variable resistance nonvolatile storage element (hereinafter, also referred to as a “memory cell”) after a first pulse that has the same polarity as and a shorter pulse width than the first write pulse and a second pulse that has the same polarity as a second write pulse whose polarity is opposite to that of the first write pulse are applied in this order. This improves the retention characteristics in the on state while securing a memory window in a ReRAM.

### CITATION LIST

### Patent Literature

PTL 1: Japanese Unexamined Patent Application Publication No. 2017-004579

### SUMMARY

### Technical Problem

However, the technique of PTL 1 has a problem of the possibility of deterioration in endurance (i.e., rewrite durability) characteristics since additional pulses (i.e., the first pulse and the second pulse) are applied to the memory cell in addition to the original write pulse (i.e., the first write pulse) in the first write process. In other words, there is a problem of sacrificing the endurance characteristics.

In view of the above, the present disclosure provides a variable resistance nonvolatile storage device and a method for driving a variable resistance nonvolatile storage element that can reduce deterioration of retention without increasing the number of times writing is performed.

### Solution to Problem

A variable resistance nonvolatile storage device according to one aspect of the present disclosure includes: a variable resistance nonvolatile storage element including: a first electrode layer; a second electrode layer; a variable resistance layer sandwiched between the first electrode layer and the second electrode layer; a first terminal connected to the first electrode layer; and a second terminal connected to the second electrode layer; and a heater including: a heating element; and a third terminal and a fourth terminal each connected to the heating element, in which the variable resistance nonvolatile storage element and the heater are independently operable and thermally coupled to each other.

A method for driving a variable resistance nonvolatile storage element according to one aspect of the present disclosure is a method for driving a variable resistance nonvolatile storage element switchable between a high-resistance state and a low-resistance state. The method includes: a high-resistance switching process of driving the variable resistance nonvolatile storage element to bring the variable resistance nonvolatile storage element into the high-resistance state; a low-resistance switching process of driving the variable resistance nonvolatile storage element to bring the variable resistance nonvolatile storage element into the low-resistance state; and a heating process of driving a heater at some point while the variable resistance nonvolatile storage element is selected for the high-resistance switching process, the heater being thermally coupled to the variable resistance nonvolatile storage element.

### Advantageous Effects

The present disclosure can provide a variable resistance nonvolatile storage device and a method for driving a variable resistance nonvolatile storage element that can reduce deterioration of retention without increasing the number of times writing is performed.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A is a schematic diagram illustrating a first exemplary structure of a variable resistance nonvolatile storage device according to an embodiment.

FIG. 1B is a schematic diagram illustrating a second exemplary structure of the variable resistance nonvolatile storage device according to the embodiment.

FIG. 1C is a schematic diagram illustrating a third exemplary structure of the variable resistance nonvolatile storage device according to the embodiment.

FIG. 2 is a diagram illustrating an exemplary circuit configuration of the variable resistance nonvolatile storage device according to the embodiment.

FIG. 3 is a timing chart illustrating a method for driving a memory cell according to the embodiment.

FIG. 4A is a diagram illustrating retention characteristics of the memory cell after a cycling test in which conventional writing to bring into a high-resistance state without “application of heat” and writing to bring into a low-resistance state (where the write current is 125 μA) are alternately repeated.

FIG. 4B is a diagram illustrating retention characteristics of the memory cell after a cycling test in which conventional writing to bring into a high-resistance state without “application of heat” and writing to bring into a low-resistance state (where the write current is 75 μA) are alternately repeated.

FIG. 4C is a diagram illustrating retention characteristics of the memory cell after a cycling test in which writing to bring into a high-resistance state according to the embodiment with “application of heat” and writing to bring into a low-resistance state (where the write current is 75 μA) are alternately repeated.

FIG. 5 is a diagram for explaining the feature of a method for driving the memory cell according to the embodiment in comparison with a conventional method.

FIG. 6 is a diagram for explaining an event that occurs when the cell current in the high-resistance state is decreased through another conventional method in which applied voltage for an erasing operation is increased, while comparing the embodiment and the conventional method.

FIG. 7 is a schematic structure diagram of the memory cell for explaining a transition mechanism of the cell current shown in FIG. 5 and FIG. 6.

FIG. 8A is a timing chart illustrating a method for driving the memory cell according to variation 1 of the embodiment.

FIG. 8B is a timing chart illustrating a method for driving the memory cell according to variation 2 of the embodiment.

### DESCRIPTION OF EMBODIMENT

Hereinafter, an embodiment of the present disclosure will be described in detail with reference to the drawings. It should be noted that the embodiment described below presents one specific example. The numerical values, shapes, materials, constituent components, the arrangement and connection of the constituent components, operation timings, steps, the order of steps, etc., described in the following embodiment are mere examples, and therefore are not intended to limit the present disclosure. Moreover, the respective figures are not necessarily precise illustrations. In the respective figures, elements that are substantially the same are given the same reference signs, and duplicated descriptions may be omitted or simplified. Furthermore, “A and B are connected” means that A and B are electrically connected, and includes not only the case where A and B are directly connected but also the case where A and B are indirectly connected with another circuit element interposed between A and B. Furthermore, “above” and “below” refer to a relative direction in the illustrated state, and do not indicate a relationship with the vertical direction.

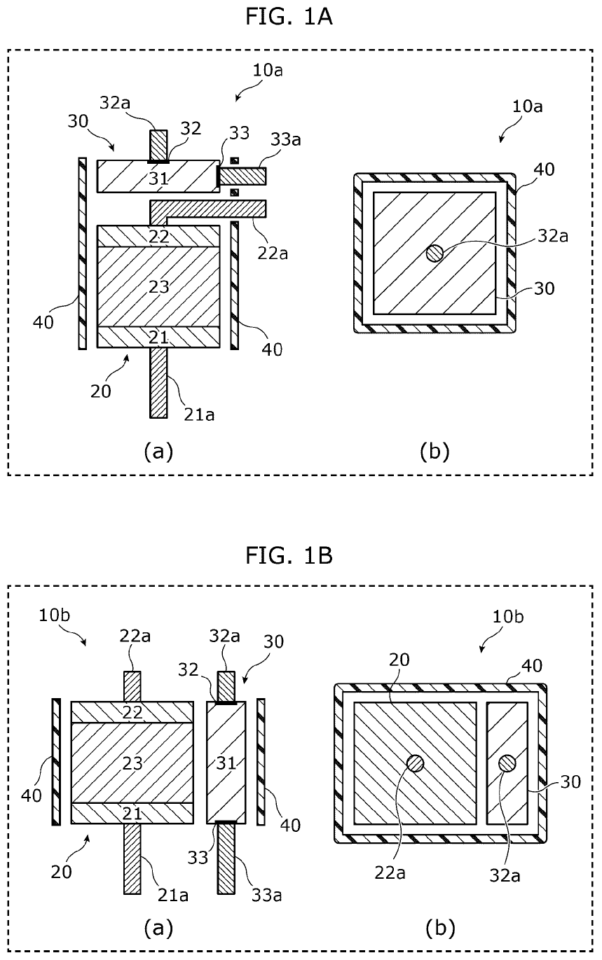

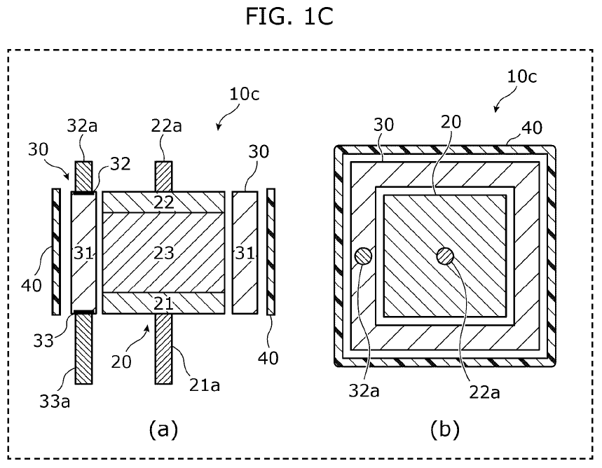

FIG. 1A is a schematic diagram illustrating a first exemplary structure of variable resistance nonvolatile storage device 10a according to an embodiment. More specifically, part (a) of FIG. 1A is a sectional view of variable resistance nonvolatile storage device 10a, and part (b) of FIG. 1A is a top view of variable resistance nonvolatile storage device 10a.

Variable resistance nonvolatile storage device 10a is a ReRAM, which is a single-chip semiconductor device, and is characterized in that memory cell 20, which is a variable resistance nonvolatile storage element, and heater 30 thermally coupled to memory cell 20 are included, and memory cell 20 and heater 30 are independently operable. Memory cell 20 includes first electrode layer 21, second electrode layer 22, and variable resistance layer 23 sandwiched between first electrode layer 21 and second electrode layer 22. Heater 30 includes heating element 31, and third terminal 32 and fourth terminal 33 each connected to heating element 31. In the present embodiment, variable resistance nonvolatile storage device 10a further includes heat shield structure 40 that reduces transmission of heat generated in heater 30 to outside variable resistance nonvolatile storage device 10a. However, heat shield structure 40 is not an essential constituent component of variable resistance nonvolatile storage device 10a.

It should be noted that “independently operable” for two circuit elements means connection by which it is allowed that the operation of one of the two circuit elements has no effect on the operation of the other. For example, this means that each of the two circuit elements independently has a terminal for operating the circuit element. Moreover, “thermally coupled” for two circuit elements means a relationship in which heat generated by one of the two circuit elements is transmitted to the other, and includes not only the case where the two circuit elements are in direct contact with each other but also the case where the two circuit elements are in indirect contact with each other via another object.

In the present exemplary structure, heater 30 is aligned with memory cell 20 (here, arranged above memory cell 20) in the stacking direction of first electrode layer 21, second electrode layer 22, and variable resistance layer 23. Moreover, heat shield structure 40 surrounds memory cell 20 and heater 30 when seen in the stacking direction of first electrode layer 21, second electrode layer 22, and variable resistance layer 23. It should be note that the “stacking direction” is also a direction perpendicular to the front surface or the back surface of a wafer on which variable resistance nonvolatile storage device 10a is formed.

Hereinafter, constituent components of variable resistance nonvolatile storage device 10a will be described in detail.

Memory cell 20 is a nonvolatile variable resistance element that switches between a high-resistance state and a low-resistance state depending on a voltage applied between first electrode layer 21 and second electrode layer 22. For example, memory cell 20 switches to the high-resistance state when a positive voltage is applied to second electrode layer 22 with respect to a voltage applied to first electrode layer 21, and switches to the low-resistance state when a negative voltage is applied to second electrode layer 22 with respect to a voltage applied to first electrode layer 21.

First electrode layer 21 is an electrode to which line 21a, which is one example of the first terminal, is connected. For example, first electrode layer 21 includes a transition metal nitride such as a tantalum nitride or a titanium nitride, or stacked layers thereof. Second electrode layer 22 is an electrode to which line 22a, which is one example of the second terminal, is connected. For example, second electrode layer 22 includes platinum, iridium, palladium, silver, nickel, tungsten, cupper, or the like. Variable resistance layer 23 includes a minute local region where oxygen deficiency reversibly changes depending on the polarity of the applied voltage (i.e., a filament region formed from an oxygen-deficient site). For example, variable resistance layer 23 is formed by stacking a first variable resistance layer in contact with first electrode layer 21 (a low-resistive tantalum oxide layer including an oxygen-deficient Ta oxide) and a second variable resistance layer in contact with second electrode layer 22 (a high-resistive tantalum oxide layer).

Heating element 31 of heater 30 has relatively high resistance, and includes a material that generates a relatively large amount of heat when current flows through heating element 31. For example, heating element 31 includes a titanium nitride, a titanium aluminum nitride, a titanium tungsten, a tantalum nitride, a tantalum silicon nitride, a tungsten nitride, or the like. Third terminal 32 is one of the terminals of heating element 31 to which line 32a is connected, and fourth terminal 33 is the other of the terminals of heating element 31 to which line 33a is connected.

Heat shield structure 40 is a heat insulator with low heat conductivity. For example, heat shield structure 40 includes a silicon oxide, a low-permittivity material, a porous silicon oxide, an aerogel, a xerogel, or the like.

As shown in part (b) of FIG. 1A, in the top view, memory cell 20 and heater 30 are rectangular shaped, and heat shield structure 40 is rectangular ring-shaped. It should be noted that the heat shield structure may be formed as one body, or may be formed as separated portions. Variable resistance nonvolatile storage device 10a including these constituent components is manufactured by using a semiconductor substrate and repeating processes such as a film forming process and a photolithography process.

Moreover, in the present exemplary structure, heater 30 is arranged above memory cell 20 as a position aligned with memory cell 20 in the stacking direction of first electrode layer 21, second electrode layer 22, and variable resistance layer 23, but the position in the stacking direction is not limited to such an upward position. Instead of or in addition to such an upward position, heater 30 may be arranged below memory cell 20.

FIG. 1B is a schematic diagram illustrating a second exemplary structure of variable resistance nonvolatile storage device 10b according to the embodiment. More specifically, part (a) of FIG. 1B is a sectional view of variable resistance nonvolatile storage device 10b, and part (b) of FIG. 1B is a top view of variable resistance nonvolatile storage device 10b.

The present exemplary structure differs from the first exemplary structure shown in FIG. 1A in that heater 30 is aligned with memory cell 20 in a direction perpendicular to the stacking direction of first electrode layer 21, second electrode layer 22, and variable resistance layer 23. Even in such a position, heater 30 is thermally coupled to memory cell 20. It should be note that the “direction perpendicular to the stacking direction” is also a direction perpendicular to a sectional view of a wafer on which variable resistance nonvolatile storage device 10b is formed.

It should be noted that, in the present exemplary structure, heater 30 is opposed to one of side surfaces of memory cell 20 as a position aligned with memory cell 20 in the direction perpendicular to the stacking direction of first electrode layer 21, second electrode layer 22, and variable resistance layer 23, but the position in the direction perpendicular to the stacking direction is not limited to this position. Heater 30 may be opposed to two or more of four side surfaces of memory cell 20.

Moreover, in addition to heater 30 according to the present exemplary structure, heater 30 according to the first exemplary structure may be added. When heaters 30 are provided in positions for one memory cell 20, these heaters 30 may be electrically connected in series or in parallel.

FIG. 1C is a schematic diagram illustrating a third exemplary structure of variable resistance nonvolatile storage device 10c according to the embodiment. More specifically, part (a) of FIG. 1C is a sectional view of variable resistance nonvolatile storage device 10c, and part (b) of FIG. 1C is a top view of variable resistance nonvolatile storage device 10c.

The present exemplary structure differs from the first exemplary structure shown in FIG. 1A in that heater 30 surrounds memory cell 20 when seen in the stacking direction of first electrode layer 21, second electrode layer 22, and variable resistance layer 23. Even in such a position, heater 30 is thermally coupled to memory cell 20. It should be noted that “when seen in the stacking direction” also means “when seen from the front surface or the back surface of a wafer on which variable resistance nonvolatile storage device 10c is formed”.

It should be noted that, in the present exemplary structure, heater 30 surrounds memory cell 20 when seen in the stacking direction of first electrode layer 21, second electrode layer 22, and variable resistance layer 23, but the position surrounding memory cell 20 is not limited to this. It is also possible to surround memory cell 20 when seen in the direction perpendicular to the stacking direction.

Moreover, in addition to heater 30 according to the present exemplary structure, heater 30 according to the first exemplary structure and/or heater 30 according to the second exemplary structure may be added. When heaters 30 are provided in positions for one memory cell 20, these heaters 30 may be electrically connected in series or in parallel.

Moreover, in any of the exemplary structures shown in FIG. 1A through FIG. 1C, a pair of memory cell 20 and heater 30 is illustrated, but when it is assumed that this pair is 1 bit, multiple bits may be arranged in a two-dimensional form or in a three-dimensional form. In this case, heat shield structure 40 is located at the boundary of each bit.

In other words, in the exemplary structure described above, heat shield structure 40 surrounds memory cell 20 and heater 30 when seen in the stacking direction of first electrode layer 21, second electrode layer 22, and variable resistance layer 23, but the position surrounding memory cell 20 and heater 30 is not limited to this. It is also possible to surround memory cell 20 and heater 30 when seen in the direction perpendicular to the stacking direction.

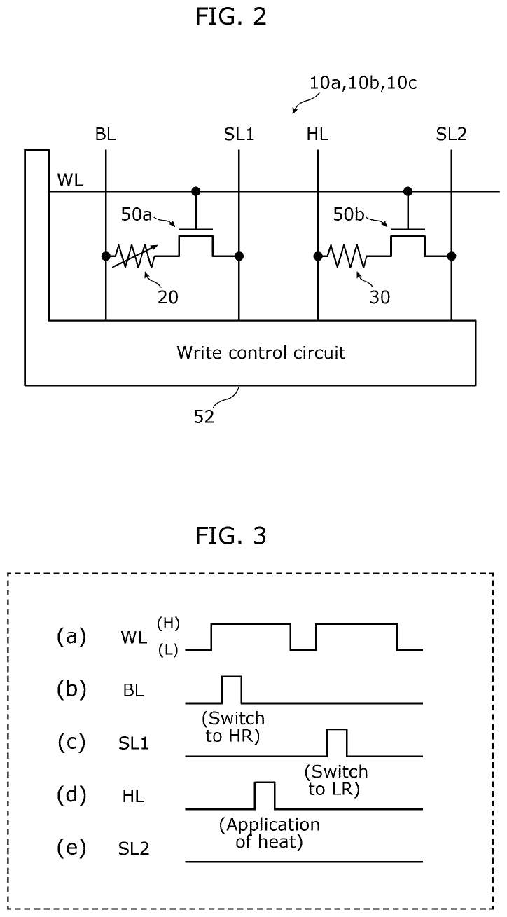

FIG. 2 is a diagram illustrating an exemplary circuit configuration of variable resistance nonvolatile storage devices 10a through 10c according to the embodiment. This diagram illustrates an exemplary circuit configuration in which, in addition to memory cell 20 and heater 30 shown in FIG. 1A through FIG. 1C, transistors 50a and 50b and write control circuit 52 are added.

As illustrated in this diagram, memory cell 20 and transistor 50a for driving memory cell 20 are connected in series, and heater 30 and transistor 50b for driving heater 30 are connected in series. The control terminals (i.e., the gate terminals) of transistors 50a and 50b are connected to word line WL, one terminal (e.g., first electrode layer 21) of memory cell 20 is connected to bit line BL, the other terminal (e.g., second electrode layer 22) of memory cell 20 is connected to one input/output terminal (e.g., one of the source and the drain) of transistor 50a, the other input/output terminal (e.g., the other of the source and the drain) of transistor 50a is connected to source line SL1, one terminal (e.g., third terminal 32) of heater 30 is connected to heater driving line HL, the other terminal (e.g., fourth terminal 33) of heater 30 is connected to one input/output terminal (e.g., one of the source and the drain) of transistor 50b, and the other input/output terminal (e.g., the other of the source and the drain) of transistor 50b is connected to source line SL2.

By outputting signals to word line WL, bit line BL, source line SL1, heater driving line HL, and source line SL2 as described later with reference to FIG. 3, write control circuit 52 performs: switch-to-HR writing that causes memory cell 20 to transition to a high-resistance state (hereinafter, also referred to as a “high-resistance switching process”, a “switch to HR”, or an “erasure operation”); heating of memory cell 20 (hereinafter, also referred to as a “heating process”, or “application of heat”); and switch-to-LR writing that causes memory cell 20 to transition to a low-resistance state (hereinafter, also referred to as a “low-resistance switching process”, a “switch to LR”, or a “write operation”). Accordingly, write control circuit 52 includes: a selection circuit that outputs a selection signal to the word line (not illustrated); a voltage source circuit that supplies voltage pulses or constant voltage to bit line BL, source line SL1, heater driving line HL, and source line SL2 (not illustrated); and a processor that controls the selection circuit and the voltage source circuit (not illustrated).

Moreover, in the exemplary circuit configuration in this diagram, a pair of memory cell 20 and heater 30 is illustrated, but when it is assumed that this pair is 1 bit, multiple bits may be arranged in a two-dimensional form or in a three-dimensional form.

FIG. 3 is a timing chart illustrating a method for driving memory cell 20 according to the embodiment. More specifically, parts (a) through (e) of FIG. 3 illustrate signals for word line WL, bit line BL, source line SL1, heater driving line HL, and source line SL2 in the exemplary circuit configuration of FIG. 2, respectively. This diagram illustrates exemplary driving in which writing to bring into a high-resistance state (a “switch to HR” and “application of heat”) and writing to bring into a low-resistance state (a “switch to LR”) are performed on memory cell 20 in this order by the exemplary circuit configuration illustrated in FIG. 2.

The writing to bring into a high-resistance state (a “switch to HR” and “application of heat”) according to the present embodiment is characterized in that both a “switch to HR” and “application of heat” are performed although a “switch to HR” is only performed in the conventional writing. Specifically, write control circuit 52: drives word line WL to the selected level (i.e., H level), thereby placing transistors 50a and 50b into a conductive state; applies a voltage pulse for a “switch to HR” (e.g., 1.7 V) to bit line BL while keeping source line SL1 at a reference potential, and then a voltage pulse for “application of heat” (e.g., 3.0 V) to heater driving line HL while keeping source line SL2 at a reference potential; and, drives word line WL to the non-selected level (i.e., L level). In this manner, the voltage pulse for a “switch to HR” is applied to memory cell 20 and then the voltage pulse for “application of heat” is applied to heater 30, and thus the writing to bring into a high-resistance state can be performed to reduce deterioration in the retention of memory cell 20.

The subsequent writing to bring into a low-resistance state (a “switch to LR”) is the same as the conventional writing. Specifically, write control circuit 52: drives word line WL to the selected level (i.e., H level), thereby placing transistors 50a and 50b into a conductive state; applies a voltage pulse for a “switch to LR” (e.g., 2.0 V) to source line SL1 while keeping bit line BL at a reference potential; and, drives word line WL to the non-selected level (i.e., L level). In the writing to bring into a low-resistance state, “application of heat” is not performed.

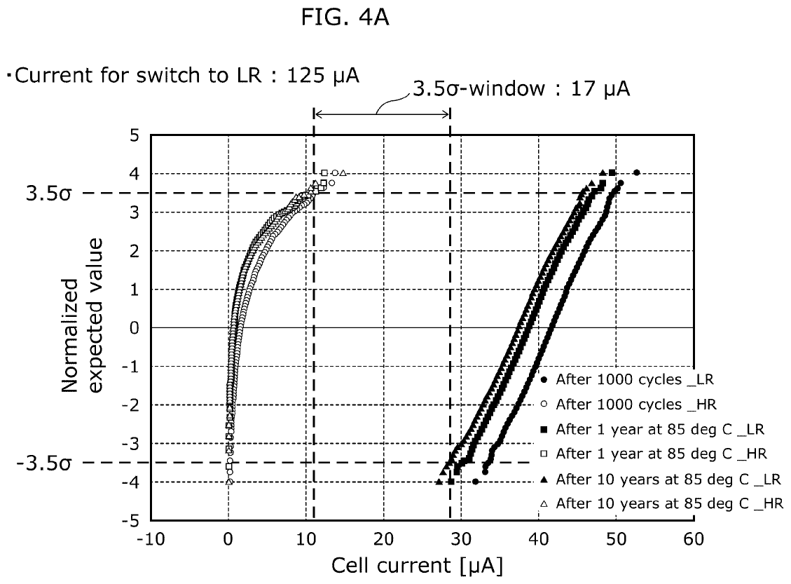

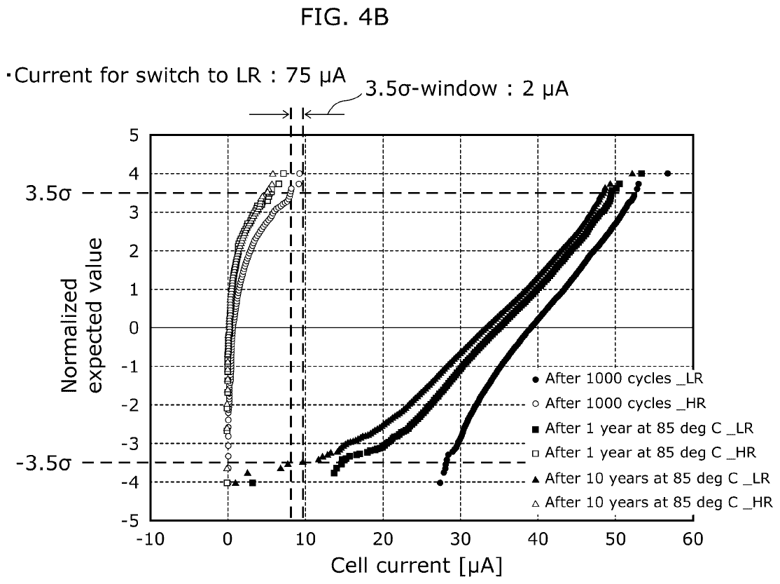

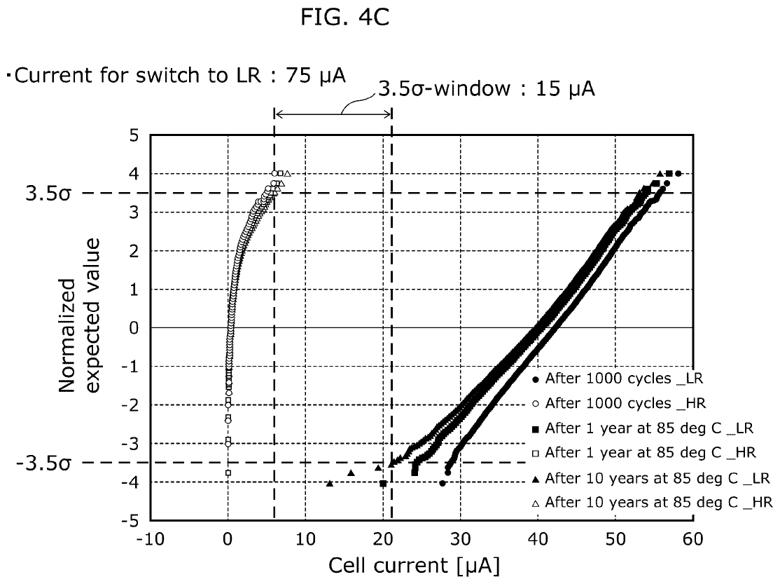

FIG. 4A through FIG. 4C is a diagram for explaining the effect caused by a method for driving memory cell 20 according to the embodiment. More specifically, FIG. 4A illustrates retention characteristics of the memory cell after a cycling test in which conventional writing to bring into a high-resistance state without “application of heat” and writing to bring into a low-resistance state (where a write current is 125 μA) are alternately repeated, FIG. 4B illustrates retention characteristics of the memory cell after a cycling test in which conventional writing to bring into a high-resistance state without “application of heat” and writing to bring into a low-resistance state (where a write current is 75 μA) are alternately repeated, and FIG. 4C illustrates retention characteristics of the memory cell after a cycling test in which writing to bring into a high-resistance state according to the embodiment with “application of heat” and writing to bring into a low-resistance state (where a write current is 75 μA) are alternately repeated.

By performing, on a certain number of memory cells having the same property, a cycling test in which a cycle of writing to bring into a high-resistance state and writing to bring into a low-resistance state is repeated 1000 times and then performing an accelerated aging test, the retention characteristics are plotted as normalized expected values (expected values in units of standard deviation σ; the y axis) of current (“cell current”) corresponding to resistance values in a high-resistance state and in a low-resistance state of each of the memory cells after the elapse of 1 year at 85 degrees C. and after the elapse of 10 years at 85 degrees C. The horizontal axis denotes “cell current”.

In each of FIG. 4A through FIG. 4C, a series of black-circle plots, a series of black-square plots, and a series of black-triangle plots indicate normalized expected values of cell current in a low-resistance state after the cycling test, after the elapse of 1 year at 85 degrees C., and after the elapse of 10 years at 85 degrees C., respectively. A series of white-circle plots, a series of white-square plots, and a series of white-triangle plots indicate normalized expected values of cell current in a high-resistance state after the cycling test, after the elapse of 1 year at 85 degrees C., and after the elapse of 10 years at 85 degrees C., respectively.

As can be seen from FIG. 4A, when the conventional writing to bring into a high-resistance state without “application of heat” is performed using a relatively large write current (i.e., 125 μA), a window of only about 17 μA is secured which is a distance between the minimum resistance value in a high-resistance state and the maximum resistance value in a low-resistance state of each memory cell after the elapse of 10 years at 85 degrees C. (specifically, a window in the ±3.5σ range of normalized expected values (hereinafter, also referred to as a ±3.5σ-window)). It should be noted that σ is the standard deviation in the distribution of resistance values.

However, as can be seen from FIG. 4B, when the conventional writing to bring into a high-resistance state without “application of heat” is performed using a relatively small write current (i.e., 75 μA), the ±3.5σ-window of each memory cell after the elapse of 10 years at 85 degrees C. is about 2 μA and extremely small. The retention characteristics of the memory cell deteriorate significantly. This is because the resistance value of the memory cell in the low-resistance state increases (i.e., the cell current decreases).

In contrast, as can be seen from FIG. 4C, when the writing to bring into a high-resistance state according to the embodiment with “application of heat” is performed using a relatively small write current (i.e., 75 μA), the ±3.5σ-window after the elapse of 10 years at 85 degrees C. is about 15 μA. The deterioration in retention characteristics of the memory cell is significantly reduced.

In recent years, with the miniaturization of semiconductor devices, high reliability in a low-power operation has been demanded. Unfortunately, as can be seen from FIG. 4A and FIG. 4B, in the conventional method of driving a memory cell without “application of heat”, the amount of deterioration in retention after cycling increases when the write current is decreased. Accordingly, it is impossible to keep an adequate memory window and ensure the high reliability. In contrast, as can be seen from FIG. 4C, the writing to bring into a high-resistance state according to the embodiment with “application of heat” can reduce the amount of deterioration in retention after cycling even when the write current is decreased. Accordingly, it is achieved by the writing to bring into a high-resistance state according to the embodiment with “application of heat” that high reliability in a low-power operation is ensured in variable resistance nonvolatile storage devices 10a through 10c.

Furthermore, the writing to bring into a high-resistance state according to the embodiment with “application of heat” can reduce deterioration in the retention of memory cell 20 without scarifying the endurance characteristics of memory cell 20 as in the conventional method that increases the number of times writing is performed.

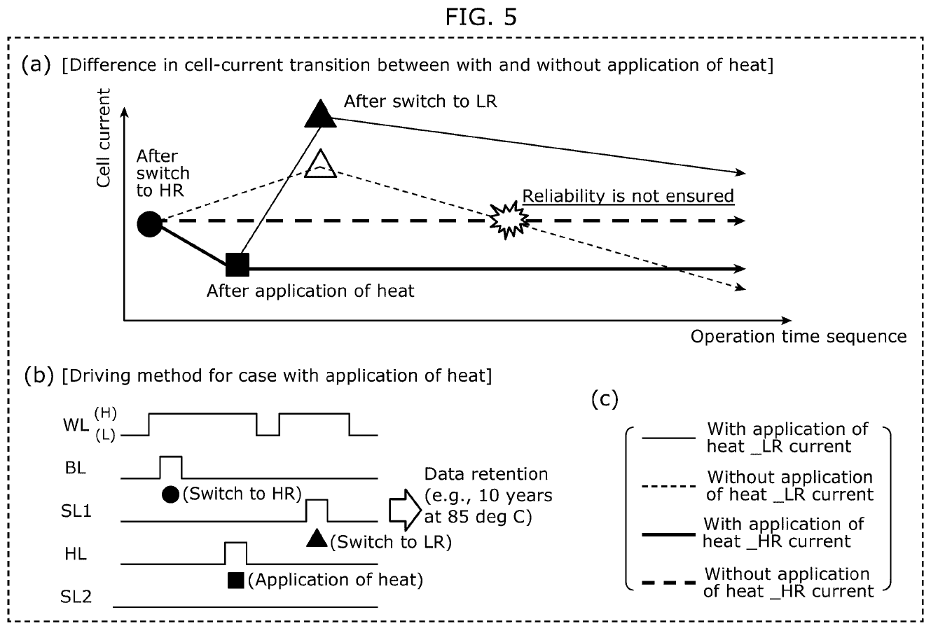

The following describes the feature of a method for driving a memory cell according to the present embodiment with reference to FIG. 5 through FIG. 7, and also includes a comparison with the conventional method and a mechanism in the memory cell.

FIG. 5 is a diagram for explaining the feature of a method for driving memory cell 20 according to the present embodiment in comparison with a conventional method. More specifically, part (a) of FIG. 5 illustrates a cell-current transition in the first conventional example in which normal erasure voltage VH is applied to bring into a high-resistance state, and a cell-current transition in the present embodiment in which the same is performed and then “application of heat” is further performed to decrease the cell current in the high-resistance state. The horizontal axis denotes the operation time sequence, and the vertical axis denotes the cell current. Part (b) of FIG. 5 illustrates operation timings corresponding to a “switch to HR”, “application of heat”, a “switch to LR”, and thereafter in part (a) of FIG. 5. Part (c) of FIG. 5 illustrates the meanings of the line types indicating their respective transitions in part (a) of FIG. 5.

As illustrated in (a) of FIG. 5, in the method for driving memory cell 20 according to the present embodiment (the transitions denoted by the thick solid line and the thin solid line passing through the black circle, black square, and black triangle), variable resistance layer 23 of memory cell 20 is oxidized by performing “application of heat” on memory cell 20 after a “switch to HR”, thereby decreasing oxygen deficiencies in a filament region formed in variable resistance layer 23. In other words, in comparison with the case where “application of heat” is not performed (the transitions denoted by the thick dotted line and the thin dotted line), the cell current in the high-resistance state is low. As the result, in the subsequent “switch to LR”, a higher voltage is applied to memory cell 20 than in the case where “application of heat” is not performed, thereby increasing the oxygen deficiencies in the filament region. In other words, in comparison with the case where a heat treatment is not performed, the cell current in the low resistance state is high since the oxygen deficiencies in the filament region increase. This reduces decrease in cell current caused by decrease in oxygen deficiencies (re-oxidation) that occurs over time, and leads to the improvement of the reliability.

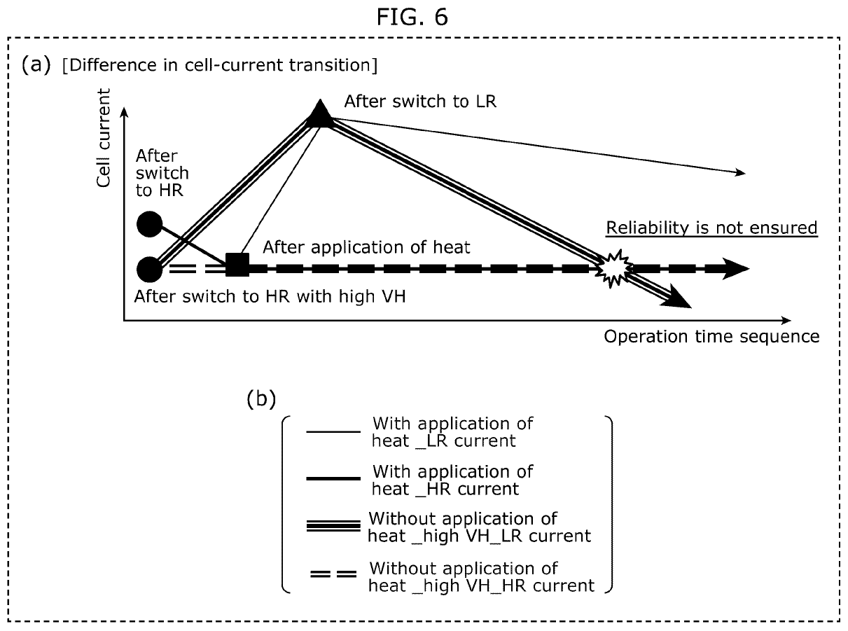

FIG. 6 is a diagram for explaining the feature of the method for driving memory cell 20 according to the present embodiment in comparison with a second conventional method. More specifically, part (a) of FIG. 6 illustrates a cell-current transition after a “switch to LR” following a “switch to HR” in the second conventional example in which erasure voltage VH is increased as a method of decreasing the cell current in the high-resistance state, and a cell-current transition after a “switch to LR” following a “switch to HR” in the present embodiment in which a “switch to HR” is performed and then “application of heat” is further performed as a method of decreasing the cell current in the high-resistance state. The horizontal axis denotes the operation time sequence, and the vertical axis denotes the cell current. Part (b) of FIG. 6 illustrates the meanings of the line types indicating their respective transitions in part (a) of FIG. 6.

As illustrated by the transitions in the second conventional example in which erasure voltage VH is increased (the transitions denoted by the double line and the triple line) in part (a) of FIG. 6, in the second conventional example, the cell current in the high-resistance state is decreased by increasing a pulse voltage applied to the memory cell in switching to a high-resistance state. As the result, in the subsequent “switch to LR”, a higher voltage is applied to memory cell 20 than in the first conventional example in which normal erasure voltage VH is applied to bring into a high-resistance state, thereby increasing oxygen deficiencies in a filament region to increase the cell current in the low-resistance state. However, after this process, the cell current decreases over time, and a problem of increase in the deterioration of retention arises.

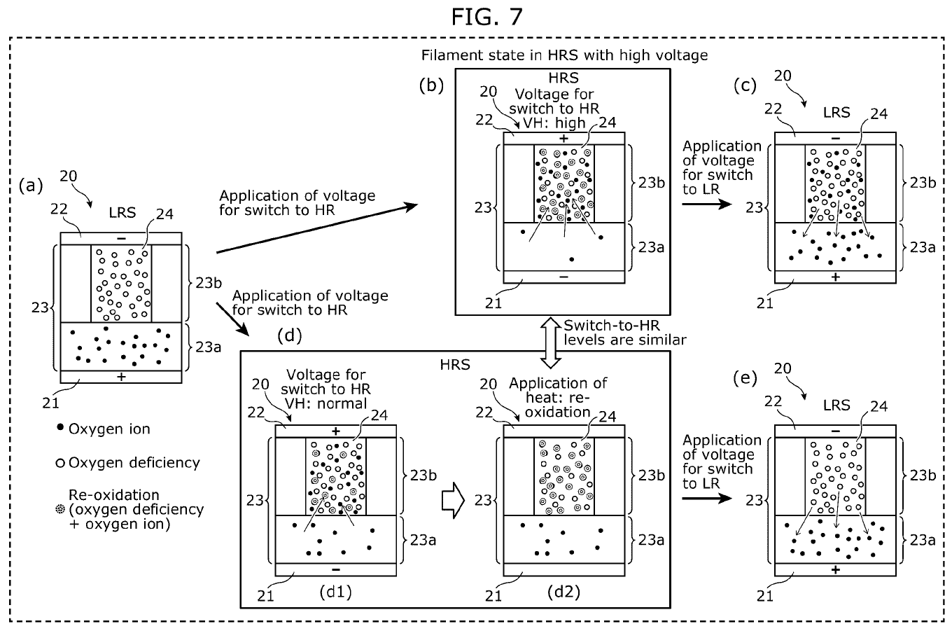

In contrast, as illustrated by the transitions with “application of heat” (the transitions denoted by the thin solid line and the thick solid line) in part (a) of FIG. 6, in the present embodiment, “application of heat” is performed after a “switch to HR”, and thus variable resistance layer 23 of memory cell 20 is oxidized, thereby decreasing oxygen deficiencies in a filament region formed in variable resistance layer 23. As the result, in the subsequent “switch to LR”, a high voltage is applied to memory cell 20, thereby increasing the oxygen deficiencies in the filament region to increase the cell current in the low-resistance state. However, in the driving according to the present embodiment, decrease in cell current that occurs over time is reduced, and thus the reliability is improved. FIG. 7 is a schematic structure diagram of memory cell 20 for explaining a transition mechanism of the cell current shown in FIG. 6.

Part (a) of FIG. 7 illustrates a schematic structure of memory cell 20 in a low-resistance state (“LRS”). Variable resistance layer 23 includes: first variable resistance layer 23a including oxygen ions; and second variable resistance layer 23b in which filament 24 including oxygen deficiencies are formed.

Part (b) of FIG. 7 illustrates a schematic structure of memory cell 20 in a high-resistance state (“HRS”) after memory cell 20 in the state illustrated in part (a) of FIG. 7 is switched to a high-resistance state using a high erasure voltage, i.e., using a write voltage higher than a normal write voltage (“switch to HR voltage VH: high”), through the conventional driving method. Although re-oxidation occurs by the oxygen ions in first variable resistance layer 23a moving to filament 24 in second variable resistance layer 23b and coupling to the oxygen deficiencies in filament 24, many oxygen ions not contributing to the re-oxidation are left in the filament.

Part (c) of FIG. 7 illustrates a schematic structure of memory cell 20 in a low-resistance state (“LRS”) after memory cell 20 in the state illustrated in part (b) of FIG. 7 is switched to a low-resistance state by applying a write voltage for bring into the low-resistance state (“application of voltage to switch to LR”). Although the oxygen ions in filament 24 move to first variable resistance layer 23a, many oxygen ions still remain in filament 24. As the result, when memory cell 20 is retained in this state for a long time, re-oxidation of the oxygen deficiencies occurs in filament 24 and the oxygen deficiencies are getting fewer, thereby decreasing the cell current in the low-resistance state (i.e., deterioration of the retention progresses).

In contrast, part (d) of FIG. 7 illustrates a schematic structure of memory cell 20 in a high-resistance state (“HRS”) after memory cell 20 in the state illustrated in part (a) of FIG. 7 is switched to a high-resistance state using a normal erasure voltage (“switch to HR voltage VH: normal”) as in the transition to part (b) of FIG. 7 (part (d1) of FIG. 7) and “application of heat” is further performed on memory cell 20 to change to a higher resistance state (part (d2) of FIG. 7), through the driving method according to the present embodiment. “Application of heat” causes re-oxidation by coupling the oxygen ions to the oxygen deficiencies in filament 24, thereby decreasing the oxygen deficiencies.

Part (e) of FIG. 7 illustrates a schematic structure of memory cell 20 in a low-resistance state (“LRS”) after memory cell 20 in the state illustrated in part (d) of FIG. 7 is switched to a low-resistance state by applying a write voltage for bring into the low-resistance state (“application of voltage to switch to LR”). Although the oxygen ions in filament 24 move to first variable resistance layer 23a, oxygen ions in filament 24 are few. As the result, even when memory cell 20 is retained in this state for a long time, re-oxidation of the oxygen deficiencies rarely occurs. Accordingly, deterioration of the retention is reduced.

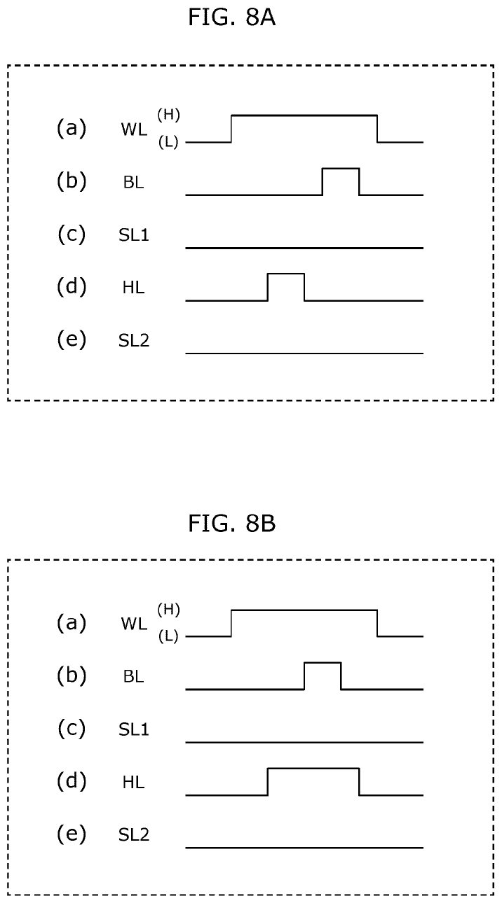

It should be noted that, in the present embodiment, as illustrated in FIG. 3, “application of heat” is performed after a “switch to HR” in the erasure operation to bring memory cell 20 into a high-resistance state (a “switch to HR” and “application of heat”), but the present disclosure is not limited to this order. A “switch to HR” may be performed after “application of heat” as illustrated in the timing chart according to Variation 1 of FIG. 8A, or a “switch to HR” and “application of heat” may be performed in parallel as illustrated in the timing chart according to Variation 2 of FIG. 8B. In other words, the order of a “switch to HR” and “application of heat” is not particularly limited as long as the variable resistance nonvolatile storage element is selected for the high-resistance switching process. The order of a “switch to HR” and “application of heat”, and the pulse width of “application of heat” are appropriately determined according to the heat capacity of memory cell 20, the amount of heat from heater 30, the degree of thermal coupling of memory cell 20 and heater 30, and the like.

As described above, variable resistance nonvolatile storage device 10a or the like according to the present embodiment includes: memory cell 20 that is a variable resistance nonvolatile storage element; and heater 30 thermally coupled to memory cell 20, and memory cell 20 and heater 30 are independently operable. Memory cell 20 includes first electrode layer 21, second electrode layer 22, and variable resistance layer 23 sandwiched between first electrode layer 21 and second electrode layer 22, and heater 30 includes heating element 31, and third terminal 32 and fourth terminal 33 each connected to heating element 31.

With this, heater 30 can be used to apply heat to memory cell 20 in writing to bring memory cell 20 into a high-resistance state, thereby achieving the decreased cell current of memory cell 20 after switching to a high-resistance state and the increased cell current of memory cell 20 after switching to a low-resistance state. Accordingly, it is possible to reduce deterioration in the retention of memory cell 20 without scarifying the endurance characteristics of memory cell 20 as in the conventional method that increases the number of times writing is performed. Furthermore, deterioration of the retention is reduced even in low-current writing, thereby achieving that high reliability in a low-power operation is ensured in the variable resistance nonvolatile storage device.

Here, heater 30 may be aligned with memory cell 20 in the stacking direction of first electrode layer 21, second electrode layer 22, and variable resistance layer 23, or may be aligned with memory cell 20 in a direction perpendicular to the stacking direction of first electrode layer 21, second electrode layer 22, and variable resistance layer 23. Alternatively, heater 30 may surround memory cell 20 when seen in the stacking direction, or may surround memory cell 20 when seen in a direction perpendicular to the stacking direction. With this, heater 30 can be thermally coupled to memory cell 20 according to various configurations.

Moreover, variable resistance nonvolatile storage device 10a or the like may further includes heat shield structure 40 that reduces transmission of heat generated in heater 30 to outside variable resistance nonvolatile storage device 10a or the like. This reduces the loss of the heat generated in heater 30 to outside the device, and thus it is possible to ensure the efficient application of heat and reduce the thermal effect on other memory cells and the like arranged adjacent to memory cell 20.

In doing so, heat shield structure 40 may surround memory cell 20 and heater 30 when seen in the stacking direction of first electrode layer 21, second electrode layer 22, and variable resistance layer 23, or may surround memory cell 20 and heater 30 when seen in a direction perpendicular to the stacking direction. With this, application of heat to memory cell 20 is more secured.

Moreover, the method for driving memory cell 20 according to the present embodiment is a method for driving memory cell 20 switchable between a high-resistance state and a low-resistance state, and includes: a high-resistance switching process of driving memory cell 20 to bring memory cell 20 into the high-resistance state; a low-resistance switching process of driving memory cell 20 to bring memory cell 20 into the low-resistance state; and a heating process of driving heater 30 thermally coupled to memory cell 20, at some point while memory cell 20 is selected for the high-resistance switching process.

With this, the high-resistance switching process and the heating process are performed for writing to bring memory cell 20 into a high-resistance state, thereby achieving the decreased cell current of memory cell 20 after switching to a high-resistance state and the increased cell current of memory cell 20 after switching to a low-resistance state.

Accordingly, it is possible to reduce deterioration in the retention of memory cell 20 without scarifying the endurance characteristics of memory cell 20 as in the conventional method that increases the number of times writing is performed. Furthermore, deterioration of the retention is reduced even in low-current writing, thereby achieving that high reliability in a low-power operation is ensured in the variable resistance nonvolatile storage device.

Here, in the heating process, heater 30 may be driven while memory cell 20 is selected for the high-resistance switching process, or heater 30 may be driven after memory cell 20 is driven through the high-resistance switching process. This ensures the decreased cell current of memory cell 20 after switching to a high-resistance state and the increased cell current of memory cell 20 after switching to a low-resistance state.

Although a variable resistance nonvolatile storage device and a method for driving a variable resistance nonvolatile storage element according to the present disclosure have been described based on the embodiment and variations, the present disclosure is not limited to these embodiment and variations. The present disclosure also encompasses a variable resistance nonvolatile storage device and a method for driving a variable resistance nonvolatile storage element that are acquired by applying, to the embodiment and variations, various modifications that may be conceived by those skilled in the art, and other embodiments configured by combining some of elements or processes in the embodiment and variations, unless departing from the spirit of the present disclosure.

For example, in the foregoing embodiment, a Ta oxide layer is taken as an example of variable resistance layer 23 of memory cell 20, but the present disclosure is not limited to this material. A metal oxide layer including, as base metal, at least one of aluminum and a transition metal such as hafnium, titanium, zirconium, niobium, tungsten, nickel, or iron is also possible. Variable resistance layer 23 of memory cell 20 is not limited to the layered structure of two types of variable resistance layers. A single type of variable resistance layer is also possible.

Moreover, the exemplary circuit configuration according to the foregoing embodiment illustrates the 1T1R bit-cell formed by memory cell 20 and transistor 50a connected in series, but 1D1R bit-cell formed by memory cell 20 and a diode connected in series is also possible.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

A variable resistance nonvolatile storage device according to the present disclosure is applicable as a ReRAM in which deterioration of retention is reduced, particularly, a ReRAM in which high reliability in a low-power operation is ensured.

1. A variable resistance nonvolatile storage device comprising:
a variable resistance nonvolatile storage element including: a first electrode layer; a second electrode layer; a variable resistance layer sandwiched between the first electrode layer and the second electrode layer; a first terminal connected to the first electrode layer; and a second terminal connected to the second electrode layer; and
a heater including: a heating element; and a third terminal and a fourth terminal each connected to the heating element, wherein
the variable resistance nonvolatile storage element and the heater are independently operable and thermally coupled to each other.

2. The variable resistance nonvolatile storage device according to claim 1, wherein
the heater is aligned with the variable resistance nonvolatile storage element in a stacking direction of the first electrode layer, the second electrode layer, and the variable resistance layer.

3. The variable resistance nonvolatile storage device according to claim 1, wherein
the heater is aligned with the variable resistance nonvolatile storage element in a direction perpendicular to a stacking direction of the first electrode layer, the second electrode layer, and the variable resistance layer.

4. The variable resistance nonvolatile storage device according to claim 1, wherein
the heater surrounds the variable resistance nonvolatile storage element when seen in a stacking direction of the first electrode layer, the second electrode layer, and the variable resistance layer.

5. The variable resistance nonvolatile storage device according to claim 1, wherein
the heater surrounds the variable resistance nonvolatile storage element when seen in a direction perpendicular to a stacking direction of the first electrode layer, the second electrode layer, and the variable resistance layer.

6. The variable resistance nonvolatile storage device according to claim 1, further comprising:
a heat shield structure that reduces transmission of heat generated in the heater to outside the variable resistance nonvolatile storage device.

7. The variable resistance nonvolatile storage device according to claim 6, wherein
the heat shield structure surrounds the variable resistance nonvolatile storage element and the heater when seen in a stacking direction of the first electrode layer, the second electrode layer, and the variable resistance layer.

8. The variable resistance nonvolatile storage device according to claim 6, wherein
the heat shield structure surrounds the variable resistance nonvolatile storage element and the heater when seen in a direction perpendicular to a stacking direction of the first electrode layer, the second electrode layer, and the variable resistance layer.

9. A method for driving a variable resistance nonvolatile storage element switchable between a high-resistance state and a low-resistance state, the method comprising:
a high-resistance switching process of driving the variable resistance nonvolatile storage element to bring the variable resistance nonvolatile storage element into the high-resistance state;
a low-resistance switching process of driving the variable resistance nonvolatile storage element to bring the variable resistance nonvolatile storage element into the low-resistance state; and
a heating process of driving a heater at some point while the variable resistance nonvolatile storage element is selected for the high-resistance switching process, the heater being thermally coupled to the variable resistance nonvolatile storage element.

10. The method for driving the variable resistance nonvolatile storage element according to claim 9, wherein
in the high-resistance switching process, the variable resistance nonvolatile storage element is driven after the heater is driven through the heating process.

11. The method for driving the variable resistance nonvolatile storage element according to claim 9, wherein
in the heating process, the heater is driven after the variable resistance nonvolatile storage element is driven through the high-resistance switching process.
